(19) United States
(12) Patent Application Publication
(10) Pub. No.: US 2023/0337507 A1
(43) Pub. Date: Oct. 19, 2023

(54) DISPLAY SUBSTRATE, PREPARATION METHOD THEREOF AND DISPLAY DEVICE

(71) Applicants: CHONGQING BOE DISPLAY TECHNOLOGY CO., LTD., Chongqing (CN); BOE TECHNOLOGY GROUP CO., LTD., Beijing (CN)

(72) Inventors: Xinwei WU, Beijing (CN); Zhen ZHANG, Beijing (CN); Wei ZHANG, Beijing (CN); Jonguk KWAK, Beijing (CN); Cunzhi LI, Beijing (CN)

(73) Assignees: CHONGQING BOE DISPLAY TECHNOLOGY CO., LTD., Chongqing (CN); BOE TECHNOLOGY GROUP CO., LTD., Beijing (CN)

(21) Appl. No.: 17/044,845

(22) PCT Filed: Apr. 3, 2020
(86) PCT No.: PCT/CN2020/083196

§ 371 Date: Oct. 1, 2020

(30) Foreign Application Priority Data
Jun. 20, 2019 (CN) 201910537995.8

(51) Int. Cl. H10K 59/80; H10K 59/122; H10K 59/12; H10K 59/131; H10K 71/00

(52) U.S. Cl. CPC H10K 59/873; H10K 59/122; H10K 59/1201; H10K 59/131; H10K 71/00

(57) ABSTRACT

A display substrate includes a cut-out area; a display region; and an isolation region including an isolation pillar and at least two packing dams; a base substrate; a barrier layer; a buffer layer; a first gate insulation layer; a second gate insulation layer; and an interlayer insulation layer. The isolation pillar is formed of a portion of the barrier layer, a portion of the buffer layer, a portion of the first gate insulation layer, a portion of the second gate insulation layer, and a portion the interlayer insulation layer. A side of the side end surface proximal to the substrate is indented inward compared to the side facing away from the substrate. A light emitting layer on the side of the structural layer facing away from the substrate is discontinuous at least at a position having an indented structure.

### CROSS-REFERENCE TO RELATED APPLICATION

The present application claims priority to Chinese Patent Application No. 201910537995.8 filed on Jun. 20, 2019, the disclosure of which is hereby incorporated by reference in its entirety.

### FIELD

The present disclosure relates generally to the field of display technologies, and more specifically to a display substrate, a method for manufacturing the same, and a display device.

### BACKGROUND

For mobile phone screens, most manufacturers are pursuing a higher screen-to-body ratios, in order to bring more visual impact to customers.

### SUMMARY

Various embodiments of the disclosure can mitigate the problem that water and oxygen may easily enter the display area horizontally along the organic layer and cause an organic light-emitting diode (OLED) display device to fail when a camera is installed in the screen.

In an aspect, a display substrate is provided, including:
a cut-out area;
a display region surrounding the cut-out area; and
an isolation region surrounding the cut-out area being located between the cut-out area and the display area, the isolation region including at least one isolation pillar and at least two packing dams;
wherein the display substrate further includes:
a base substrate having a barrier layer;
a buffer layer on the base substrate;
a first gate insulation layer on the buffer layer;
a second gate insulation layer on the first gate insulation layer; and
an interlayer insulation layer on the second gate insulation layer;
wherein:
the at least one isolation pillar is formed of a portion of the barrier layer, a portion of the buffer layer, a portion of the first gate insulation layer, a portion of the second gate insulation layer, and a portion the interlayer insulation layer;
the isolation pillar having at least one side end surface being provided in the isolation region;
an indented structure is formed at least along part of the end surface of the isolation pillar, wherein the side of the side end surface proximal to the substrate is indented inward compared to the side facing away from the substrate;
a light emitting layer is provided on the side of the structural layer facing away from the substrate, and the light emitting layer is discontinuous at least at a position having an indented structure.

In some embodiments, the base substrate includes:
a first polyimide layer; and
a first barrier layer on the first polyimide layer; wherein the barrier layer and the buffer layer are above the first barrier layer.

In some embodiments, the indented structure forms at any single layer or combination of the barrier layer, the buffer layer, the first gate insulation layer, the second gate insulation layer, and the interlayer insulation layer.

In some embodiments, a first layer of the at least one isolation pillar is formed having a first etching pattern.

In some embodiments, a second layer of the at least one isolation pillar is formed having a second etching pattern.

In some embodiments, the cut-out area includes a cutting opening and a plurality of layers surrounding the cutting opening and the plurality of layers are in a same layer with the barrier layer, the buffer layer, the first gate insulation layer, the second gate insulation layer and the interlayer insulation layer.

In some embodiments, the display substrate further includes a metal line between two layers of any two of a portion of the barrier layer, a portion of the buffer layer, a portion of the first gate insulation layer, a portion of the second gate insulation layer, and a portion the interlayer insulation layer.

In some embodiments, the indented structure is further formed at side end surface of the metal line.

In some embodiments, the metal line is in a same layer with an electrode in the display region.

In some embodiments, the display region includes a driving thin film transistor and a storage capacitor with a first capacitor electrode and a second capacitor electrode.

In some embodiments, the driving thin film transistor includes a driving gate in a same layer with the first capacitor electrode

In some embodiments, the metal line is in a same layer with the second capacitor electrode.

In some embodiments, the display substrate further includes:
a circuit structure within the display region;
a pixel-defining structure provided above the circuit structure within the display region;
an anode provided above the pixel-defining area, wherein the light-emitting layer is disposed above the anode; and
a cathode being provided above the light-emitting layer.

In another aspect, a display substrate is provided, including:
a substrate having a first surface and a second surface, wherein the first surface includes a display region about a central portion thereof,
a cut-out portion provided within the display region and an isolation portion extending around a perimeter thereof between the cut-out portion and the display region;
one or more structural layers provided on a first surface of the substrate, at least one structural layer extending into the isolation portion about a perimeter edge thereof;
an indented structure disposed about a portion of the perimeter edge of the one or more structural layers;
wherein the indented structure tapers from a wider portion at an opposing surface of the one or more structural layers being opposite from the substrate to a narrower portion being nearer the substrate; and
a light emitting layer being provided over a furthest most structural layer on a side of the furthest most structural layer being opposite the substrate.

In some embodiments, the display substrate further includes:
a plurality of structural layers, each of the plurality of structural layers including a perimeter portion extending into the isolation region, a first of the structural layers abutting the substrate, a second structural layer abutting the first structural layer on a side being opposite the substrate;
wherein a perimeter portion of the first structural layer extends a further distance into the isolation portion of the substrate than a perimeter portion of the second structural layer, thus forming one or more steps.

In some embodiments, each of the plurality of structural layers including a perimeter portion extending into the isolation region, and wherein each of the perimeter portions of each structural layer includes an indent structure about a portion of a perimeter edge thereof.

In some embodiments, the light emitting layer includes one or more breaks located proximal each of the one or more step so as to form one or more discontinuities at a position corresponding with the perimeter edge portion of each of the one or more structural layers.

In another aspect, a method for manufacturing a display substrate is provided, wherein the display substrate includes a base substrate, the base substrate includes a display area, and an isolation region located at an edge of the display area; and the method includes:
forming at least one structural layer having a side end surface in the isolation region; the side end surface is located in the isolation region;
forming an indented structure positioned at least about a portion of the side end surface, and a side of the side end surface proximal to the substrate is more indented inward compared to a side away from the substrate; and
forming a light emitting layer across the display area and the isolation region;
wherein the light emitting layer is provided with one or more breaks at one or more positions proximal the indented structure.

In some embodiments, the at least one structural layer includes
a barrier layer of the base substrate, a buffer layer on the base substrate,
a first gate insulation layer on the buffer layer, a second gate insulation layer on the first gate insulation layer, an interlayer insulation layer on the second gate insulation layer.

In some embodiments, the method for manufacturing a display substrate further includes forming a metal line between two layers of any two of a portion of the barrier layer, a portion of the buffer layer, a portion of the first gate insulation layer, a portion of the second gate insulation layer, and a portion the interlayer insulation layer, and wherein the method further includes forming the indented structure at side end surface of the metal line.

It should be noted that the above general description and the following detailed description are merely exemplary and explanatory and should not be construed as limiting of the present disclosure.

### BRIEF DESCRIPTION OF THE DRAWINGS

To more clearly illustrate some of the embodiments, the following is a brief description of the drawings. The drawings in the following descriptions are only illustrative of some embodiments. For those of ordinary skill in the art, other drawings of other embodiments can become apparent based these drawings.

FIG. 1A illustrates a schematic view of an exemplary full-screen mobile terminal;

FIG. 1B illustrates a side cross-sectional view of the device about a camera or sensor area and extending into the display area as indicated in the area A-A of FIG. 1A, explicitly illustrating an arrangement of isolation pillars configured to block a common light-emitting material layer being illustrative of various concepts in accordance with certain aspects of the present disclosure;

FIG. 1C illustrates a scanning electron microscopic view of an exemplary light-emitting-material blocking structure in accordance with various aspects of the present disclosure;

FIG. 2 illustrates a schematic diagram of a manufacturing process of a display substrate according to various aspects of the present disclosure;

FIG. 3 illustrates a schematic diagram of a manufacturing process of a display substrate according to various additional aspects of the present disclosure;

FIG. 4 illustrates a schematic diagram of a manufacturing process of a display substrate according to various additional aspects of the present disclosure;

FIG. 5 illustrates an exemplary side cross-sectional schematic structural diagram of a display substrate according to another embodiment of the present disclosure;

FIG. 6 illustrates an exemplary side cross-sectional schematic structural diagram of another display substrate according to another embodiment of the present disclosure;

FIG. 7, illustrates an exemplary side cross-sectional schematic structural diagram of a flexible display substrate which can be configured to utilize any of the display substrates in accordance with any of the embodiments disclosed herein;

FIG. 8, illustrates an exemplary side cross-sectional schematic structural diagram of various etch buffer layers which can be applied and removed during the manufacturing processes of the display substrates as contemplated herein;

FIG. 9 illustrates an exemplary side cross-sectional schematic structural diagram of a display substrate with various layer films having a single source drain; and

FIG. 10 illustrates an exemplary side cross-sectional schematic structural diagram of a display substrate with various layer films having a dual source drain.

### DETAILED DESCRIPTION

The embodiments set forth below represent the necessary information to enable those of ordinary skill in the art to practice the embodiments and illustrate the best mode of practicing the embodiments. Upon reading the following description in light of the accompanying drawing figures, those of ordinary skill in the art will understand the concepts of the disclosure and will recognize applications of these concepts not particularly addressed herein. It should be understood that these concepts and applications fall within the scope of the disclosure and the accompanying claims.

The various embodiments and aspects of the present invention will be discussed with reference to the accompanying figures, in which the following reference numerals indicate the following associated components thereon: 1 represents a substrate; 11 represents a display area; 12 represents an isolation region; 13 represents a cut-out area; 2 represents a structural layer; 21 represents a first structural layer; 22 represents a second structural layer; 3 represents an indented structure; 31 represents a first indented structure; 32 represents a second indented structure; 4 represents a light-emitting layer; 41 represents a pixel-defining structure; 42 represents an anode; 43 represents a cathode; 44 represents a packaging layer; 45 represents a first Dam, 46 represents a second Dam, 47 represents a fifth Dam, 48 represents isolation pillars, 49 represents source drains, and 5 represents a metal line.

The inventors of the present disclosure have recognized that at least the following problems exist in related OLED screens.

The presence of a camera and various sensors which share a surface with a display screen has historically restricted the development of OLED screens which can achieve a fully optimal or increased screen ratio. At present, placing the camera and some sensors inside the screen is receiving great attention from the industry. However, because the light-emitting layer of the display area is formed by covering the entire surface or layer, in the process of forming a camera in the screen, water and oxygen in the air easily enter the display area horizontally along the light-emitting layer, and chemical reactions occur with the organic light-emitting material in the light-emitting unit. Such chemical reactions can cause dark spots in the light-emitting areas and even cause OLED device failure.

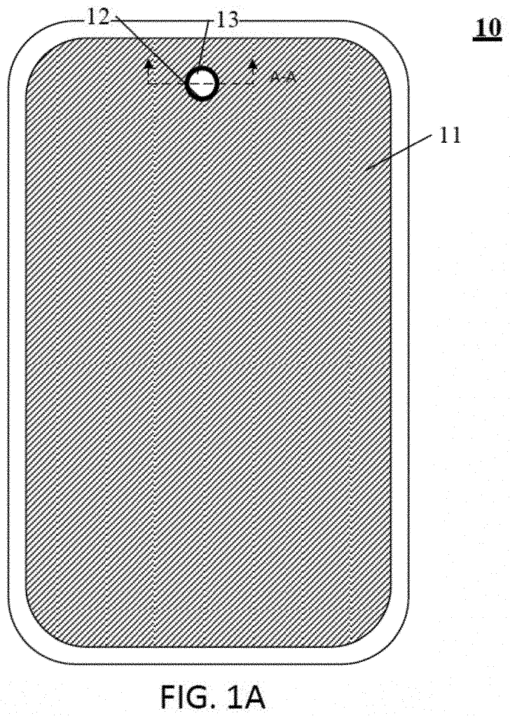

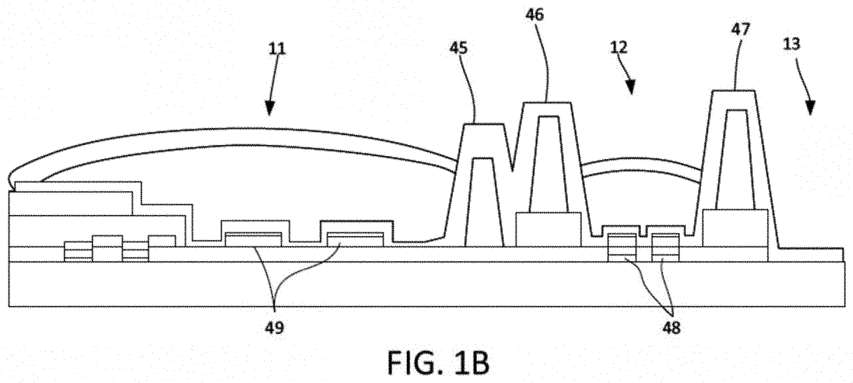

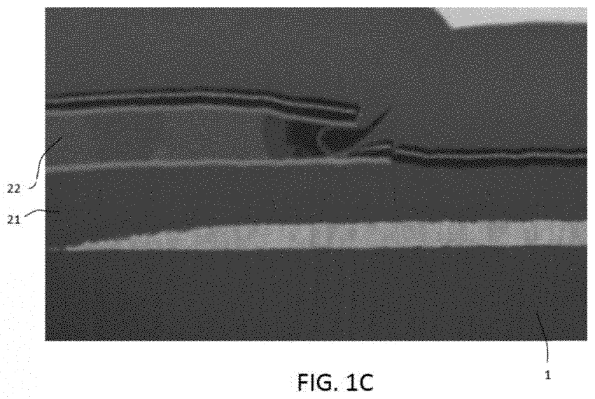

Placing the camera and some sensors inside the screen, as illustrated in an example in FIG. 1A, can be realized with a an overhanging or concave substrate design for one or more SD (source/drain) 49 or isolation pillars 49 so as to achieve a better sealing or blocking effect of chemicals or other contaminants on or across the light-emitting layer as well as provide resistance to delamination when undergoing bending stresses. In FIG. 1A, 11 represents a display area, 12 represents an isolation region, and 13 represents a cut-out area (A-A hole).

In some additional exemplary embodiments, the source drain electrode layer or the isolation pillars can be formed by providing an Ti—Al—Ti material layer in the region acting as the source drain or the isolation pillars.

FIG. 1B illustrates a side cross-sectional view of the device about a camera or sensor area and extending into the display area as indicated in the area A-A of FIG. 1A, explicitly illustrating an arrangement of isolation pillars configured to block a common light-emitting material layer.

As shown, the device can have the display area 11 with source/drains 49; the isolation region 12 with isolation pillars 48; and the cut-out area 13, separated by first and second Dams 45, 46 and a fifth Dam 47.

By taking into account of certain potential changes and design process feasibility from a perspective of structural design, various embodiments of the present disclosure can realize sealing or blocking of the common light-emitting material layer by utilizing various materials having a certain amount of water and oxygen absorption potential. In order to achieve these various structural designs of the backplane formation process will need to be altered in flat panel display technologies.

In some embodiments, one or more isolation pillars can include an undercut morphology which can be formed with a side etching process so as to remove a central core portion thereof. In some embodiments this isolation pillar can include a wafer design having upper and lower titanium layers sandwiching an aluminum layer which can be undercut utilizing the aforementioned etching process. In this manner, the light-emitting material can be sealed or blocked by the top Ti layer of the separation pillar.

FIG. 1C illustrates an actual cross-sectional view of a light-emitting-material sealing or blocking structure fabricated in this manner from the view of an electron microscope.

The process can include: EBA/EBB Mask→Carbon Nanotube (CNT) Mask→Buffered Oxide Etch (BOE Etch)→source drain Mask.

In a first example, a method for preparing a display substrate is provided.

In some exemplary embodiments of the present disclosure can include the following process steps or structures: Providing a substrate and then providing a dimethacrylate (EBA)/EBB Mask→CNT Mask→BOE Mask→1st BOE Etch→2nd BOE Etch→source drain Mask.

As contemplated herein, EBA/EBB can be utilized for a first etch for an associated inorganic layer and CNT mask can be utilized so as to form one or more apertures, vias, or holes in the insulation layer.

BOE mask etch can then be utilized so as to etch or otherwise form depressions in the side surface so as to have concave or undercut structures between the various layers as illustrated.

That is, after the CNT Mask, BOE Mask and BOE etching are added, and the exposed area is the cut-out area of AA Hole. By adjusting the etching time, EBA/EBB forms an undercut or concave shape to ensure the isolation of light emitting materials, or in other words, the light emitting layer in the OLED having an orthographic projection in the light-emitting direction above the display region of an associated display panel.

An undercut structure formed by way of BOE etching at the AA Hole cutting edge (EBA/EBB step position) can cut off the light emitting material and thus prevent the edge film from peeling away from the inner film after cutting and thus increase seal strength.

An SD mask can then be utilized so as to form a source and/or a drain in a metal layer. It will be understood that it may be difficult to ensure the same structure in different positions for typical designs of the source drain isolation column because the source drain side etching is an unstable process and may thus have inconsistent bonding surfaces which may result in separation at poorly formed etching points having unsuitable depths. In contrast, various embodiments of the present disclosure can accurately control its morphology through BOE etching time, thereby ensuring potential for fabrication utilizing mass production methods.

By controlling the etching time, the depth of the lateral depression or depth of the concave portion can be controlled and adjusted according to a particular need.

In some embodiments, an inorganic layer can be employed so as to isolate the light emitting material. Compared with a metal layer, the back-end packaging formed utilizing this structure or method can thus be provided having improved yields.

The display substrate can include a substrate 1, wherein the substrate 1 can include a display area 11 and an isolation region 12 at an edge of the display area 11.

A method of forming the display substrate can include the following preparation steps:
S1: forming at least one structural layer 2 with a side end surface being provided in the isolation region 12 of the substrate 1; the side end surface being located in the isolation region 12;
S2: forming an indented structure 3 on at least a part of the side end surface, and the side of the side end surface, or perimeter edge surface proximal to the substrate 1 is indented inward or provided with a concave surface extending inwardly as compared to the side being opposite from the substrate 1;
S3: forming a light-emitting layer 4 in the display region 11 and the isolation region 12; wherein, the light-emitting layer 4 is discontinuous or includes a break at least at a position about or proximal to the indented structure 3.

The manufacturing method of the display substrate of this embodiment creatively forms an indented structure 3 located along at least a part of the side end surface, or perimeter edge surface, wherein the lower side of the indented structure 3 can be more indented than the upper side or portion thereof. When the light-emitting layer 4 is covered above the layer 2, due to the existence of the indented structure 3, the light-emitting layer 4 will form a cross-section at the indented position, making the light-emitting layer 4 discontinuous at the side end position, which break serves so as to cut off the path in which water and oxygen in the air enters the display area 11 along the organic layer.

In another embodiment, a method for preparing another display substrate is provided.

In accordance with some embodiments of the present disclosure, a layer of Molybdenum Mo metal can be formed at the EBA/EBB step position through the gate2 mask.

By wet-etching the gate2 of the area through an Anode wet etch so as to form an appropriate associated anode pattern, in this manner the isolation morphology can be formed.

The isolation, sealing, or blocking structure can be formed at an AA Hole cutting edge (EBA/EBB step position). The inorganic layer structure on the lower metal can then be formed by modifying the gate2 mask. It will be understood, that because area is exposed during a subsequent anode wet etch, wherein the molybdenum material can then be removed by wet etching to form an inverted trapezoid structure, to achieve the overhanging or retention role of the aforementioned light emitting materials.

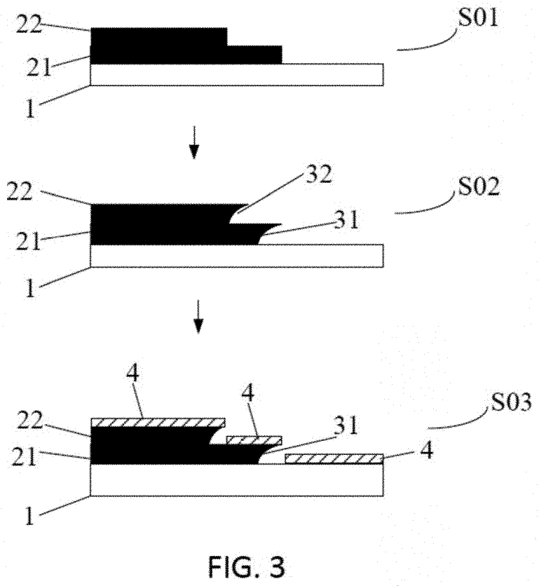

As shown in FIG. 3, the display substrate wafer or structure can include a substrate 1, wherein the substrate 1 can also include a display area 11 and an isolation region 12 at an edge of the display area 11; the method of fabrication can then include the following preparation steps:
S01: forming a plurality of structural layers 21, 22 having side end faces in the isolation region 12 of the substrate 1. The side end surface, or perimeter edge surface, of the structural layer that is farther away from the substrate 1 is closer to the display region 11; the side end surface, or perimeter edge surface of the closest structural layer is located in the isolation region 12.

That is, the multi-layer structure layer forms a plurality of steps with indented structures 31, 32 in the isolation region 12, and each step has a respective side end surface. The specific number of structural layers is not limited in this embodiment, and can be selected according to various needs in various practical applications.

In some embodiments, a single step will be sufficient, however, any number of steps can be provided in order to meet a given desirable retention or sealing parameter. The indented structures 31, 32 can be more indented than the upper side or portion thereof.

When the light-emitting layer 4 is covered above the multi-layer structure layer, due to the existence of the indented structures 31, 32, the light-emitting layer 4 will form a cross-section at the indented position, making the light-emitting layer 4 discontinuous at the side end position, which break serves so as to cut off the path in which water and oxygen in the air enters the display area 11 along the organic layer.

Generally, in the process of preparing a display substrate, a step of forming a buffer layer on the substrate 1 can also include the following steps: forming a circuit structure in the display region 11; forming a patterned anode in each sub-pixel region above the circuit structure; covering the entire light-emitting layer 4; and forming a cathode.

Specifically, a sub-process of forming a circuit structure can include the following steps or structures: forming a plurality of TFTs and leads; forming a plurality of TFTs; forming a gate; forming; forming a gate insulating layer; forming an active layer; forming an interlayer insulating layer; and forming a source/drain, etc.

In one embodiment, the multilayer structure layer in step S01 can be formed in synchronization with the insulating layer or the buffer layer of the display area 11. In some such embodiments, the structural layer can be selectively formed correspondingly in the isolation region 12 according to the insulating layer or the buffer layer of the display region 11, and a plurality of steps can be formed at the edge portions of the various different structural layers.

It should be noted that the insulating layer of the display region 11 can include a plurality of insulating layers, such as the aforementioned gate insulating layer, an interlayer insulating layer, and the like. At the same time, the specific number of structural layers and the thickness of each structural layer can be adjusted according to the specific preparation process of the display area 11. Usually, 2 to 8 steps can be selectively formed.

It can be understood that the greater the number of steps formed, the more sections of the corresponding sections of light-emitting layer 4 will need to be formed subsequently, and the better performance with regard to sealing or cutting off the passage of water and oxygen from the air into the display area 11 laterally along the organic layer.

In the following embodiment, the formation of two structural layers is taken as an example for description. Specifically, step S01 can include:

S01a: forming a first structure layer 21 in the isolation region 12 of the substrate 1, wherein the first structure layer 21 has a first side end surface; wherein the first structure layer 21 can be formed in synchronization with the buffer layer of the display region 11.

S01b: forming a second structure layer 22 on a side of the first structure layer 21 facing away from the substrate 1 or on a side of the first structure layer 21 being opposite the substrate 1, wherein the second structure layer 22 has a second side end surface, or perimeter edge surface. The second structure layer 22 can also be formed in synchronization with the insulating layer of the display area 11.

In a specific product, the sum of the thicknesses of the first structural layer 21 and the second structural layer 22 can be 1.7 μm.

In an optional implementation in this embodiment, each of the structural layers formed in step S01 can optionally be formed utilizing two different materials to form a stacked layer or wafer structure.

It can be understood that the specific material of the stacked layer or wafer structure can be selected according to various needs in a given implementation. It should be noted that, due to the subsequent need to form an indented structure that the etching rate of the material of the lower layer of the superposed layer needs to be greater than that of the material of the upper layer. In this manner, the indented structure formed at each of the side of the side end face proximal to the substrate 1 can then be more indented inward compared to the side facing away from the substrate 1.

In a specific embodiment, the two different materials include silicon oxide and silicon nitride, wherein the silicon oxide layer in a particular structure layer is disposed closer to the substrate 1 than the silicon nitride layer and will allow the concave structure to be formed as the silicon oxide will be more easily etched away than the silicon nitride which can be provided at the more distant portion of each structure layer from the substrate.

Accordingly, and as illustrated in the drawings, a step S02 can be implemented, which can include: forming a first indented structure 31 on the first side end surface, or perimeter edge surface, and forming a second indented structure 32 on the second side end surface, or perimeter edge surface; wherein the side of the side end surface, or perimeter edge surface, near the substrate 1 is indented further inward as compared to the side facing away or being opposite from the substrate 1. The first recessed structure 31 and the second recessed structure 32 may be formed simultaneously or in steps. The preferred method is to synchronize the two so as to save process time.

More specifically, the formation of the recessed structure can include: forming the recessed structure by etching with an etching solution, wherein the etching or reaction rate of the lower layer material in each structural layer by the etching solution is greater than that of the upper layer material.

The etching solution can include a mixed solution of hydrofluoric acid HF and ammonium fluoride NH4F, but can be any reactive solution which reacts in a desired manner with the structures being etched.

It should be noted that, in order to form the above-mentioned indented structure, it may also be formed by increasing the etching time.

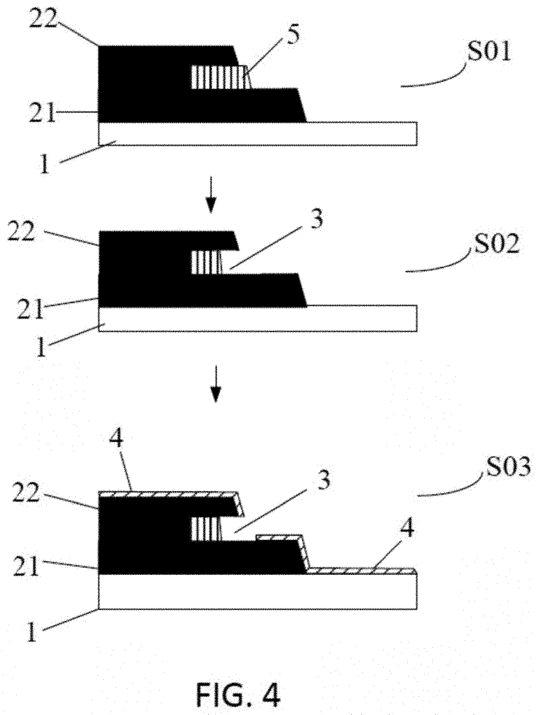

Accordingly, and as illustrated in FIG. 3 and FIG. 4, a step S03 can be implemented, which can include: forming a light emitting layer 4 in the display region 11 and the isolation region 12; wherein, the light emitting layer 4 can be provided with one or more breaks, or otherwise be discontinuous at least at a position being near or proximal an associated indented structure.

Here, the light-emitting layer 4 can be formed utilizing a vacuum evaporation process. In such embodiments, the light-emitting layer 4 can be formed of an undoped fluorescent light-emitting organic material, or an organic material doped with a fluorescent material composed of a fluorescent dopant and a matrix material. Alternatively, the light-emitting layer can be formed of an organic material doped with a phosphorescent dopant composed of a phosphorescent dopant and a matrix material. In some preferred embodiments, the thickness of the light emitting layer 4 can be provided with a thickness ranging from 10 to 50 nm.

Among them, due to the existence of the indented structure, the light emitting layer 4 can form a cross-section at the indented position, making the light emitting layer 4 discontinuous at the position of the side end face, which can then function so as to cut off or seal the passage of water and oxygen in the air into the display area 11 laterally along the organic layer.

### Example 3

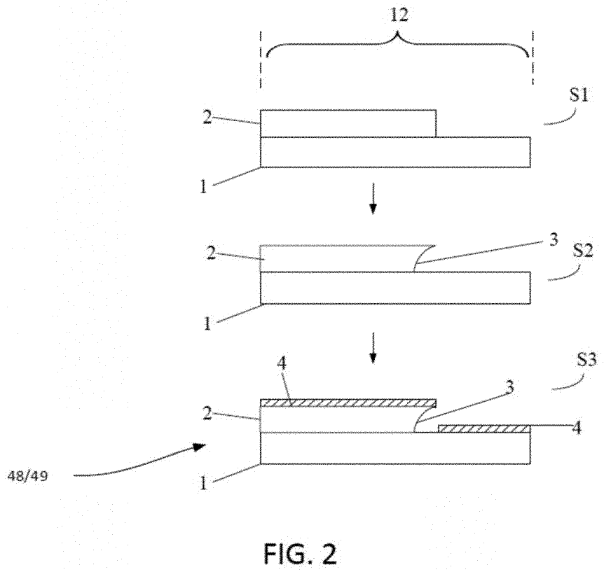

Illustrated in FIG. 4 is yet another exemplary embodiment, wherein this embodiment illustrates yet another method for preparing a display substrate. As shown in FIG. 4, the display substrate can include a substrate 1, wherein the substrate 1 can included a display area 11 and an isolation region 12 at an edge of the display area 11. The preparation method is similar to the method of FIG. 2 and FIG. 3, except that this embodiment specifically includes the following preparation steps:

S01: forming a plurality of structural layers having side end surfaces or perimeter edge surface, in the isolation region 12 of the substrate 1. Specifically, step S01 further includes: S01a: forming a first structure layer 21 in the isolation region 12 of the substrate 1, wherein the first structure layer 21 has a first side end surface, or perimeter edge surface; and wherein forming the first structure layer 21 can be performed in synchronization with a step of forming the buffer layer of the display region 11; S01b: forming a metal line 5 at an inner position of an edge of the second structure layer 22 to be formed; and S01c: forming a second structure layer 22 on a side of the first structure layer 21 facing away from the substrate 1, wherein the second structure layer 22 has a second side end surface, or perimeter edge surface.

It will be understood that the second structure layer 22 may be formed in synchronization with the insulating layer of the display area 11. Additionally, the metal line 5 can be formed using at least one of molybdenum, molybdenum-niobium alloy, aluminum, aluminum-neodymium alloy, titanium, or copper.

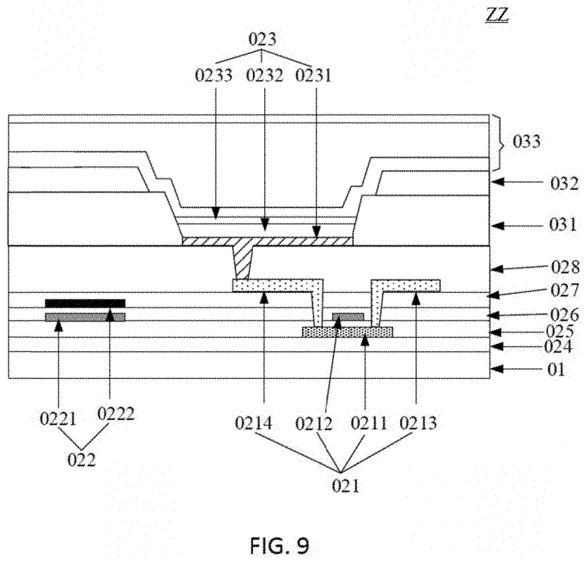

As an optional solution of this embodiment, the preparation method further includes the step of forming a second capacitor electrode 0222 of the storage capacitor 022 in the display area 11, as shown in FIG. 9, wherein the metal line 5 is formed in synchronization with a second capacitor electrode 0222 of the storage capacitor 022 of the display area 11.

Alternatively, and as illustrated in the figures, a step S02 can be implemented, which can also include: forming an indented structure along at least a portion of the side end surface, or perimeter edge surface, wherein the side of the side end surface, or perimeter edge surface, nearer the substrate 1 is indented further inward than as compared to the side facing away or opposite from the substrate 1.

Specifically, the forming the indented structure can include: etching the metal line 5 so as to form the indented structure. It will then be appreciated, that since the metal line 5 corresponds to a position located on the bottom surface of the side end surface, or perimeter edge surface, of the second structural layer 22, etching the metal line 5 corresponds to forming a hollow indented structure at this position.

In some embodiments, the manufacturing method can also further include a step of etching the patterned first electrode in the display area 11; wherein the etching of the metal line 5 can then be performed simultaneously with the etching of the first electrode.

Here, the first electrode can also be an anode, that is, the metal line 5 can be formed in the same layer as a second capacitor electrode 0222 of the storage capacitor 022 in FIG. 9 in synchronization, in which case the metal line 5 can then be simultaneously etched during the patterning of the anode.

Additionally, and as illustrated in the figures, a step S03 can be implemented, which can include: forming a light emitting layer 4 in the display region 11 and the isolation region 12; wherein, the light emitting layer 4 is discontinuous or is provided with one or more breaks each corresponding with a position having an indented structure.

In the drawings corresponding to this embodiment, the sizes, thicknesses, etc. of each structural layer shown in the drawings are shown for illustration only.

In the process realization, the projected area of each structural layer on the substrate 1 can be the same or different, and the required projected area of each structural layer can be achieved by an etching process. Further, the various structures shown in the drawings are not limited to the geometric shape of each structure layer. The shape of the layer can be provided, for example, as a rectangle as shown in the drawing, or a trapezoid, or other shapes such as curves or arcs which can be formed by etching with varying concentrations of alloys etc., all of which can also be achieved by etching.

### Example 4

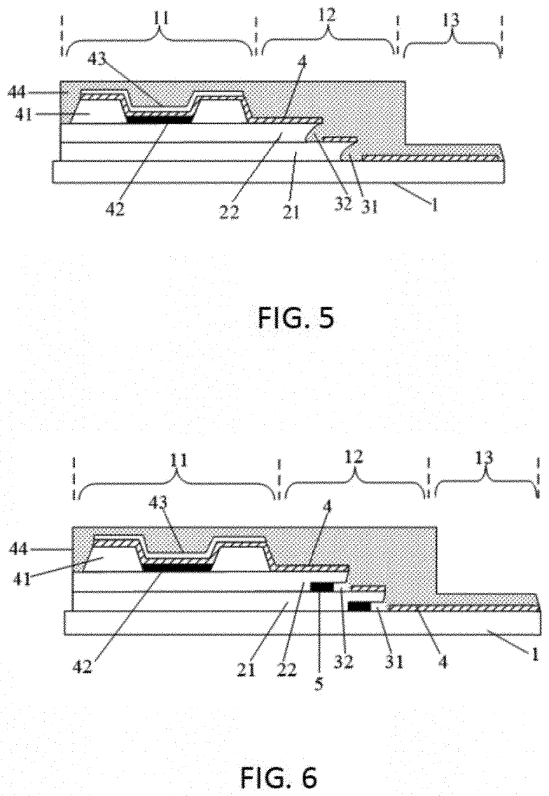

In this example, as shown in FIG. 5 and FIG. 6, wherein the display substrate can include a substrate 1, wherein the substrate 1 can includes a display area 11 and an isolation region 12 at an edge of the display area 11. As illustrated here, there can be at least one structural layer having a side end surface, or perimeter edge surface, wherein the side end surface, or perimeter edge surface, is located in the isolation region 12.

In all or part of the side end surface, or perimeter edge surface, an indented structure can then be formed wherein the side of the side end face near the substrate 1 is more indented inwardly than as compared to the side facing away or opposite from the substrate 1. A light emitting layer 4 can then subsequently be provided on a side of the structural layer facing away from the substrate 1, wherein the light emitting layer 4 can have breaks or otherwise be discontinuous at least at a position corresponding with, i.e. above, an indented structure.

The substrate 1 in this embodiment can be formed from a polyimide material, or other materials may be selected. For example, it can also be provided utilizing a transparent glass substrate or a flexible substrate made of resin.

In a specific embodiment, at least a part of the outer edge of the isolation region 12 can be further provided with a cut-out area 13, the cut-out area 13 can be a cut opening for receiving a camera component.

In a specific embodiment, a buffer layer can be further provided on the substrate 1 within the display area 11, and a circuit structure can then be provided on the buffer layer which can further include a TFT and a lead. In such an embodiment the TFT can include a gate, a gate insulating layer, an active layer, an interlayer insulating layer, a source, a drain, and the like.

Specifically, a pixel-defining structure 41 can be further provided above the circuit structure of the display area 11. The pixel-defining structure 41 can then define a pixel unit, wherein an anode 42 can be disposed in the area defined by the pixel-defining structure 41. In such embodiments, a whole layer of the light-emitting layer 4 can then be disposed above the anode 42 wherein a cathode 43 can then also be provided above the light-emitting layer 4.

In a specific embodiment, as shown in FIG. 5, the display substrate can be provided with two layers of the above-mentioned structural layers in the isolation region 12, which are a first structural layer 21 and a second structural layer 22 respectively. The second structural layer 22 can be disposed closer to the substrate 1 compared with the first structural layer 22.

The side end surface, or perimeter edge surface, which can also be referred to as a perimeter edge or perimeter edge surface, of the first structural layer 21 and the side end surface, or perimeter edge surface, of the second structural layer 22 can be configured so as to form a step; and the side end surface, or perimeter edge surface, of each structural layer can be provided having the above-mentioned indented structure.

A lateral end surface, or perimeter edge surface, of a structural layer 21 can then be provided having a first indented structure 31. A lateral end surface, or perimeter edge surface, of a second structural layer 22 can then be provided having a second indented structure 32. The light emitting layer 4 can then also be configured to have breaks or otherwise be discontinuous at a position corresponding with the lateral of each structural layer.

In another embodiment, as shown in FIG. 6, a metal line 5 can be provided at an inner position of the edge of the side end surface, or perimeter edge surface, of the structural layer, and the indented structure thereof can be obtained by etching or otherwise removing the metal line or portions thereof. The metal line 5 can be positioned in the same layer as the second capacitor electrode 0222 of the storage capacitor 022 of the display area, as also illustrated in FIG. 9, and the metal line can be etched in synchronization with the anode of the display area.

The display substrate of this embodiment can then be provided with at least one structural layer having a side end surface, or perimeter edge surface, in the isolation region 12. The side of the structural layer side end near the substrate 1 can then be indented more inwardly as compared to the side facing away from or opposite from the substrate 1. Again, the light emitting layer 4 can be provided with breaks or otherwise be discontinuous at the position of the side end, which is equivalent to seal or otherwise cut off the passage of water and oxygen in the air into the display area 11 along the organic layer.

In yet additional embodiments, as contemplated herein, a display device can be provided which can include any one of the above display substrates as discussed in the various embodiments above. The display device may be any product or component which can include a display function, such as electronic paper, OLED panel, mobile phone, tablet computer, television, display, notebook computer, digital photo frame, and navigator.

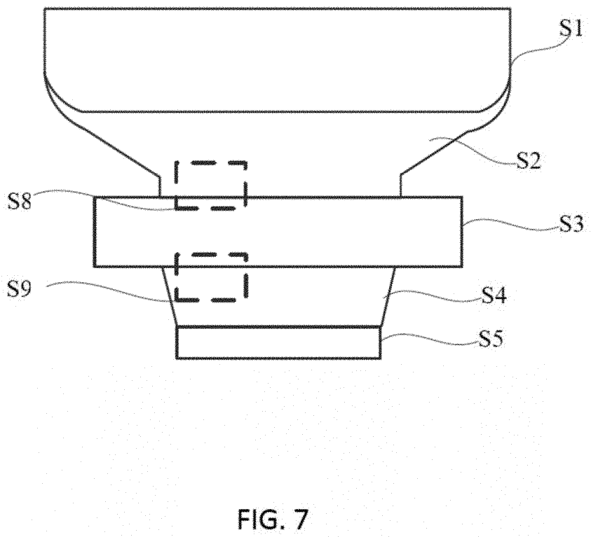

As shown in FIG. 7, the flexible display substrate can be divided into a display area S1, or in other words, a part of 11 in FIG. 1A and FIG. 1B, a first routing area S2, a bending area. S3, a second routing area S4, and an electrode binding area S5. The narrow frame of the flexible display device bends a portion of the flexible display substrate corresponding to the electrode binding region S5 in a direction facing away from the display surface.

In order to release the stress generated when the inorganic film layer in the bending region is bent, the current system omits or removes the inorganic film layers with higher hardness such as silicon oxide, silicon nitride, etc. in the bending area in advance.

There can then be provided a step difference in the bending area after removing the inorganic film layer. In order to reduce the step difference, the display area and the electrode binding area can be provided ensuring an electrical connection.

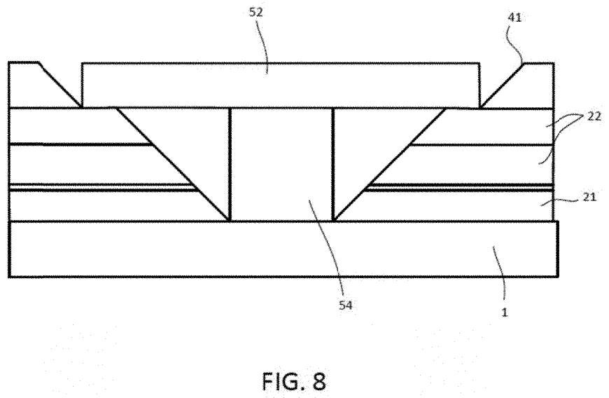

FIG. 8 illustrates an exemplary second etch or EBA 52 and an exemplary first etch or EBB 54. The removal process can then be referred to as EBA and EBB processes, wherein the film layer removal process of the bending area in some embodiments of the present invention represents an improvement of existing methods.

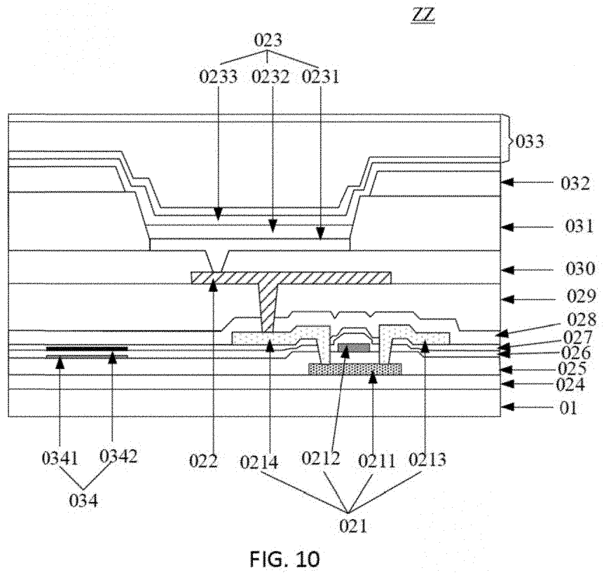

Now with regard to FIGS. 9-10, shown is a cross-sectional view of a sub-pixel driving circuit having single source drain, as shown in FIG. 9, or a dual source drain, as shown in FIG. 10.

These circuits can be provided on or within a substrate wherein a Barrer2, which can be SiOx, insulation layer, prevents water and oxygen in polyimide (PI) from entering silicon; and a buffer, which can be SiNx+SiOx, insulating layer. SiNx has good density and prevents the lower layer ions from entering the silicon. SiOx has good thermal insulation performance and plays a role of heat preservation during the Excimer Laser Annealing (ELA) process.

Also provided in the substrate can be: Poly: P-type silicon; GI1 which is an insulation layer between the P-type silicon and gate (Gate1); GI2 which is an insulation layer between two gates (Gate1/Gate2); CNT which is a contact layer, which can act as an insulating layer between the gate and the upper metal; and SD which is source and drain, or in other words metal routing for purposes of various electrical connections.

FIGS. 9-10 specifically illustrate schematic diagrams of the structure of each layer of the bending area, wherein each layer of the bending area an associated isolation column, and each layer of the display area are on the same layer. In some embodiments EBB can be used in order to etch Barrier2, and EBA can be used to etch Buffer+inline buffer dilution (ILD)+GI. However, in some alternative embodiments, particularly in situations where a pattern of the same layer as the gate2 layer is added, the processes of EBB and EBA can be adjusted such that various etching barrier2+buffer+GI, EBA are used to etch inorganic regions such as ILD in specific areas to achieve the required film thickness.

EBA and EBB can thus be performed in the bending area, and an EBC etching step can be performed in the AA Hole position, such as the camera hole; EBB can be performed first, and EBA will be performed later, wherein EBA will be used for etching based on the EBB, which is equivalent to the Bending area as illustrated. It will then be understood that as illustrated, etching will have been performed at least twice. EBB needs to etch Barrier2, EBA needs to etch Buffer+ILD+GI. After EBA and EBB etching, PI material can be filled or not, as required by product requirements.

In some embodiments, the method can also include an etching step of the Barrier2 and Buffer layers through EBB, and EBA etch ILD+GI, specific to various previously discussed embodiment of the present invention, as discussed above, except that after the etching, a step of side over-etching can be added, or in other words a BOE etch. In some exemplary embodiments, particularly wherein a gate2 metal structure is added, EBB can be utilized to etch Barrier2, buffer and GI, and EBA can be utilized to etch the ILD.

In some embodiments, the layers of the single source drain structure in the display area, or in other words barrier2, buffer, gate insulation GI, inline buffer dilution ILD, can all be provided on the same layer as the etched depressions in the exposed layers at the edge of the cut-out areas.

Specifically, as illustrated in FIG. 9, is a display layer film having a single source drain. The sub-pixel, as illustrated, can include a driving thin film transistor 021 and a storage capacitor 022. For example, the driving thin film transistor 021 can include a driving active layer 0211 on the base substrate 01, a driving gate 0212 on the side of the driving active layer 0211 opposite from the substrate 01, and a driving gate 0212 located also located opposite from the substrate 01.

The sub-pixel can then also include a side gate insulation layer, for example, including the first gate insulation layer 025 and the second gate insulation layer 026, an interlayer dielectric layer 027 located on the side of the gate insulation layer opposite from the substrate 01, and an interlayer dielectric layer 027 located on an opposing side from the substrate.

A driving source 0213 and a driving drain 0214 can then be located on the substrate 01 side. For example, the storage capacitor 022 can include a first capacitor electrode 0211 and a second capacitor electrode 0222 (formed with gate2 simultaneously). The first capacitor electrode 0211 can be located on the same layer as the driving gate 0212, and the second capacitor electrode 0222 can be located on the gate insulating layer, for example in a common layer with the second gate insulating layer 026, and interlayer dielectric layer 027.

In some exemplary embodiments, the sub-pixel 02 can further include a light-emitting diode 023. In some such embodiments, the light-emitting diode 023 can include a first electrode 0231, a light-emitting layer 0232, and a second electrode 0233 being sequentially arranged in a direction away from the substrate 01. In this manner, when a voltage is applied between the two electrodes 0233, the light emitting layer 0232 can emit light. For example, the first electrode 0231 of the light emitting diode 023 can be electrically connected to the driving drain 0214, so that the thin film transistor can control the light emitting state of the light emitting diode 023.

In yet additional embodiments, the sub-pixel can further include: a buffer layer 024 being provided on the base substrate 01, a flat layer 028 covering the driving source 0213 and the driving drain 0214, and a pixel defining layer for defining a plurality of sub-pixels 031, the support layer 032 and the packaging layer 033 and other functional structures.

For example, the pixel defining layer 031 can include a plurality of openings respectively corresponding to a plurality of sub-pixels. In this example, the light emitting diode 023 can then be formed in each of the plurality of openings. For example, the encapsulation layer 033 can include a plurality of encapsulation sublayers, such as the three-layer encapsulation sublayer shown in FIG. 9. For example, the three-layer encapsulation sublayer can then include: a first inorganic encapsulation sublayer, an organic encapsulation sublayer, and a second inorganic encapsulation sublayer disposed in a stack to enhance the encapsulation effect of the encapsulation layer 033.

In yet additional embodiments, the gate insulating layer, which can include the first gate insulating layer 025 and the second gate insulating layer 026, can be formed by using an insulating material. Additionally, the interlayer dielectric layer 027, the buffer layer 024, the flat layer 028, the pixel defining layer 031, the supporting layer 032, and the packaging layer 033 can also be formed by using an insulating material.

In response to various particular product demands, an organic insulating material such as polyimide, a resin material, or an inorganic insulating material such as silicon oxide, silicon nitride, and silicon oxynitride can be selected. However, it should be understood, that in order to achieve the various implementations of the present disclosure that those having skill in the art will recognize additional suitable materials for use in each of the functional layers.

Specifically, as shown in FIG. 10, is a display substrate with various layer films having a dual source drain. In this particular embodiment, at least one of the plurality of sub-pixels 02 in the display area AA can include a driving thin film transistor 021 and a connection electrode 022. The driving thin film transistor 021 can include a driving active layer 0211 on the base substrate 01, a driving gate 0212 on an opposing side where the driving active layer 0211 from the substrate 01, and a driving gate 0212 which can also be located opposite from the substrate 01. The drive source 0213 and the drive drain 0214 can be located about a side portion.

In this embodiment, the connection electrode 022 can then be located on a side of the driving source 0213 and the driving drain 0214 being opposite from the substrate 01. The sub-pixel as illustrated in FIG. 10 can then further include a light emitting diode 023, which can include a first electrode 0231, a light emitting layer 0232, and a second electrode 0233 which are sequentially arranged in a direction away from the substrate 01. The light emitting diode 023 can then be located at the connection electrode 022 being opposite from the substrate.

On the substrate 01 side, the driving drain 0214, the connection electrode 022, and the light emitting diode 023 can be connected in the recited order.

Further, the sub-pixels in FIG. 10 can further include: a buffer layer 024, a first gate insulating layer 025, a second gate insulating layer 026, an interlayer dielectric layer 027, and a passivation layer which are sequentially arranged in a direction away from the substrate 01. The layer 028, the first flat layer 029, the second flat layer 030, the pixel defining layer 031, the support layer 032, and the encapsulation layer 033. The driving active layer 0211 is located between the buffer layer 024 and the first gate insulating layer 025; the driving gate 0212 is located between the first gate insulating layer 025 and the second gate insulating layer 026; the driving source 0213 and the driving drain 0214 are located between the interlayer dielectric layer 027 and the passivation layer 028; the connection electrode 022 is located between the first planar layer 029 and the second planar layer 030. The pixel defining layer 031 is configured to define a pixel region on the base substrate 01, and the light emitting diode 023 is located in the pixel region.

It should be noted that the buffer layer 024, the first gate insulating layer 025, the second gate insulating layer 026, the interlayer dielectric layer 027, the passivation layer 028, the first flat layer 029, and the second flat layer 030 in the display area can all extend to a peripheral area, and the relative positional relationship of each of these film layers in the peripheral area can be the same as the relative positional relationship in the display area, which is not described in the embodiment of the present disclosure.

In addition, the sub-pixel 02 in FIG. 10 can further include a storage capacitor 034. In this embodiment, the storage capacitor 034 can include: a first capacitor electrode 0341; and a second capacitor electrode 0342. The first capacitor electrode 0341 and the driving gate 0212 can be located on the same layer, and the second capacitor electrode 0342 can be located between the second gate insulating layer 026 and the interlayer dielectric layer 027.

Optionally, part of the structure of the display area AA in the array substrate can be located on the same layer as part of the structure of the peripheral area.

It can be understood that the above embodiments are merely exemplary embodiments adopted for explaining the principle of the present disclosure, but the present disclosure is not limited thereto. For those skilled in the art, various variations and improvements can be made without departing from the spirit and essence of the present disclosure, and these variations and improvements are also considered to be within the protection scope of the present disclosure.

It is apparent that those of ordinary skill in the art can make various modifications and variations to the embodiments of the disclosure without departing from the spirit and scope of the disclosure. Thus, it is intended that the present disclosure cover the modifications and the modifications.

Various embodiments in this specification have been described in a progressive manner, where descriptions of some embodiments focus on the differences from other embodiments, and same or similar parts among the different embodiments are sometimes described together in only one embodiment.

It should also be noted that in the present disclosure, relational terms such as first and second, etc., are only used to distinguish one entity or operation from another entity or operation, and do not necessarily require or imply these entities having such an order or sequence. It does not necessarily require or imply that any such actual relationship or order exists between these entities or operations. The terms “first” and “second” are used for descriptive purposes only and are not to be construed as indicating or implying a relative importance or implicitly indicating the number of technical features indicated. Thus, elements referred to as “first” and “second” may include one or more of the features either explicitly or implicitly. In the description of the present disclosure, “a plurality” indicates two or more unless specifically defined otherwise.

Moreover, the terms “include,” “including,” or any other variations thereof are intended to cover a non-exclusive inclusion within a process, method, article, or apparatus that comprises a list of elements including not only those elements but also those that are not explicitly listed, or other elements that are inherent to such processes, methods, goods, or equipment.

In the case of no more limitation, the element defined by the sentence “includes a . . . ” does not exclude the existence of another identical element in the process, the method, or the device including the element.

In the present disclosure, it is to be understood that the terms “lower,” “upper,” “center,” “longitudinal,” “transverse,” “length,” “width,” “thickness,” “front,” “back,” “left,” “right,” “vertical,” “horizontal,” “top,” “bottom,” “inside,” “outside,” “clockwise,” “counterclockwise,” “axial,” “radial,” “circumferential,” “column,” “row,” and other orientation or positional relationships are based on example orientations illustrated in the drawings, and are merely for the convenience of the description of some embodiments, rather than indicating or implying the device or component being constructed and operated in a particular orientation. Therefore, these terms are not to be construed as limiting the scope of the present disclosure.

In the present disclosure, the terms “installed,” “connected,” “coupled,” “fixed” and the like shall be understood broadly, and may be either a fixed connection or a detachable connection, or integrated, unless otherwise explicitly defined. These terms can refer to mechanical or electrical connections, or both. Such connections can be direct connections or indirect connections through an intermediate medium. These terms can also refer to the internal connections or the interactions between elements. The specific meanings of the above terms in the present disclosure can be understood by those of ordinary skill in the art on a case-by-case basis.

In the present disclosure, a first element being “on,” “over,” or “below” a second element may indicate direct contact between the first and second elements, without contact, or indirect through an intermediate medium, unless otherwise explicitly stated and defined.

Moreover, a first element being “above,” “over,” or “at an upper surface of” a second element may indicate that the first element is directly above the second element, or merely that the first element is at a level higher than the second element. The first element “below,” “underneath,” or “at a lower surface of” the second element may indicate that the first element is directly below the second element, or merely that the first element is at a level lower than the second feature. The first and second elements may or may not be in contact with each other.

Specific examples are used herein to describe the principles and implementations of some embodiments. The description is only used to help convey understanding of the possible methods and concepts. Meanwhile, those of ordinary skill in the art can change the specific manners of implementation and application thereof without departing from the spirit of the disclosure. The contents of this specification therefore should not be construed as limiting the disclosure.

For example, in the description of the present disclosure, the terms “some embodiments,” or “example,” and the like may indicate a specific feature described in connection with the embodiment or example, a structure, a material or feature included in at least one embodiment or example. In the present disclosure, the schematic representation of the above terms is not necessarily directed to the same embodiment or example.

Moreover, the particular features, structures, materials, or characteristics described can be combined in a suitable manner in any one or more embodiments or examples. In addition, various embodiments or examples described in the specification, as well as features of various embodiments or examples, can be combined and reorganized.

In the descriptions, with respect to circuit(s), unit(s), device(s), component(s), etc., in some occurrences singular forms are used, and in some other occurrences plural forms are used in the descriptions of various embodiments. It should be noted; however, the single or plural forms are not limiting but rather are for illustrative purposes. Unless it is expressly stated that a single unit, device, or component etc. is employed, or it is expressly stated that a plurality of units, devices or components, etc. are employed, the circuit(s), unit(s), device(s), component(s), etc. can be singular, or plural.

Based on various embodiments of the present disclosure, the disclosed apparatuses, devices, and methods can be implemented in other manners. For example, the abovementioned devices can employ various methods of use or implementation as disclosed herein.

Dividing the device into different “regions,” “units,” or “layers,” etc. merely reflect various logical functions according to some embodiments, and actual implementations can have other divisions of “regions,” “units,” or “layers,” etc. realizing similar functions as described above, or without divisions. For example, multiple regions, units, or layers, etc. can be combined or can be integrated into another system. In addition, some features can be omitted, and some steps in the methods can be skipped.

Those of ordinary skill in the art will appreciate that the units, regions, or layers, etc. in the devices provided by various embodiments described above can be provided in the one or more devices described above. They can also be located in one or multiple devices that is (are) different from the example embodiments described above or illustrated in the accompanying drawings. For example, the units, regions, or layers, etc. in various embodiments described above can be integrated into one module or divided into several sub-modules.

The order of the various embodiments described above are only for the purpose of illustration, and do not represent preference of embodiments.

Although specific embodiments have been described above in detail, the description is merely for purposes of illustration. It should be appreciated, therefore, that many aspects described above are not intended as required or essential elements unless explicitly stated otherwise.

While this specification contains many specific implementation details, these should not be construed as limitations on the scope of any claims, but rather as descriptions of features specific to particular implementations. Certain features that are described in this specification in the context of separate implementations can also be implemented in combination in a single implementation. Conversely, various features that are described in the context of a single implementation can also be implemented in multiple implementations separately or in any suitable sub-combination.

Moreover, although features can be described above as acting in certain combinations and even initially claimed as such, one or more features from a claimed combination can in some cases be excised from the combination, and the claimed combination can be directed to a sub-combination or variation of a sub-combination.

Various modifications of, and equivalent acts corresponding to the disclosed aspects of the exemplary embodiments can be made in addition to those described above by a person of ordinary skill in the art having the benefit of the present disclosure without departing from the spirit and scope of the disclosure contemplated by this disclosure and as defined in the following claims. As such, the scope of this disclosure is to be accorded the broadest reasonable interpretation so as to encompass such modifications and equivalent structures.

1. A display substrate, comprising:
a cut-out area;
a display region surrounding the cut-out area; and
an isolation region surrounding the cut-out area being located between the cut-out area and the display area, the isolation region comprising at least one isolation pillar and at least two packing dams;
wherein the display substrate further comprises:
a base substrate having a barrier layer;
a buffer layer on the base substrate;
a first gate insulation layer on the buffer layer;
a second gate insulation layer on the first gate insulation layer; and
an interlayer insulation layer on the second gate insulation layer;
wherein:
the at least one isolation pillar is formed of a portion of the barrier layer, a portion of the buffer layer, a portion of the first gate insulation layer, a portion of the second gate insulation layer, and a portion the interlayer insulation layer;
the isolation pillar having at least one side end surface being provided in the isolation region;
an indented structure is formed at least along part of the end surface of the isolation pillar, wherein the side of the side end surface proximal to the substrate is indented inward compared to the side facing away from the substrate;
a light emitting layer is provided on the side of the structural layer facing away from the substrate, and the light emitting layer is discontinuous at least at a position having an indented structure.

2. The display substrate according to claim 1, wherein the base substrate comprises:
a first polyimide layer; and
a first barrier layer on the first polyimide layer; wherein the barrier layer and the buffer layer are above the first barrier layer.

3. The display substrate according to claim 1, wherein the indented structure forms at any single layer or combination of the barrier layer, the buffer layer, the first gate insulation layer, the second gate insulation layer, and the interlayer insulation layer.

4. The display substrate according to claim 1, wherein a first layer of the at least one isolation pillar is formed having a first etching pattern.

5. The display substrate according to claim 4, wherein a second layer of the at least one isolation pillar is formed having a second etching pattern.

6. The display substrate according to claim 1, wherein the cut-out area comprises a cutting opening and a plurality of layers surrounding the cutting opening and the plurality of layers are in a same layer with the barrier layer, the buffer layer, the first gate insulation layer, the second gate insulation layer and the interlayer insulation layer.

7. The display substrate according to claim 1, further comprising a metal line between two layers of any two of a portion of the barrier layer, a portion of the buffer layer, a portion of the first gate insulation layer, a portion of the second gate insulation layer, and a portion the interlayer insulation layer.

8. The display substrate according to claim 7, wherein the indented structure is further formed at side end surface of the metal line.

9. The display substrate according to claim 7, wherein the metal line is in a same layer with an electrode in the display region.

10. The display substrate according to claim 9, wherein the display region comprises a driving thin film transistor and a storage capacitor with a first capacitor electrode and a second capacitor electrode.

11. The display substrate according to claim 10, wherein the driving thin film transistor comprises a driving gate in a same layer with the first capacitor electrode.

12. The display substrate according to claim 11, wherein the metal line is in a same layer with the second capacitor electrode.

13. The display substrate according to claim 1, further comprising:
a circuit structure within the display region;
a pixel-defining structure provided above the circuit structure within the display region;
an anode provided above the pixel-defining area, wherein the light-emitting layer is disposed above the anode; and
a cathode being provided above the light-emitting layer.

14. A display substrate, comprising:
a substrate having a first surface and a second surface, wherein the first surface includes a display region about a central portion thereof,
a cut-out portion provided within the display region and an isolation portion extending around a perimeter thereof between the cut-out portion and the display region;
one or more structural layers provided on a first surface of the substrate, at least one structural layer extending into the isolation portion about a perimeter edge thereof;
an indented structure disposed about a portion of the perimeter edge of the one or more structural layers;
wherein the indented structure tapers from a wider portion at an opposing surface of the one or more structural layers being opposite from the substrate to a narrower portion being nearer the substrate; and
a light emitting layer being provided over a furthest most structural layer on a side of the furthest most structural layer being opposite the substrate.

15. The display substrate according to claim 14, further comprising:
a plurality of structural layers, each of the plurality of structural layers including a perimeter portion extending into the isolation region, a first of the structural layers abutting the substrate, a second structural layer abutting the first structural layer on a side being opposite the substrate;
wherein a perimeter portion of the first structural layer extends a further distance into the isolation portion of the substrate than a perimeter portion of the second structural layer, thus forming one or more steps.

16. The display substrate according to claim 15, wherein each of the plurality of structural layers including a perimeter portion extending into the isolation region, and wherein each of the perimeter portions of each structural layer includes an indent structure about a portion of a perimeter edge thereof.

17. The display substrate according to claim 16, wherein the light emitting layer includes one or more breaks located proximal each of the one or more step so as to form one or more discontinuities at a position corresponding with the perimeter edge portion of each of the one or more structural layers.

18. A method for manufacturing a display substrate, wherein:
the display substrate comprises a base substrate;
the base substrate comprises a display area, and an isolation region located at an edge of the display area; and
the method comprises:
forming at least one structural layer having a side end surface in the isolation region; the side end surface is located in the isolation region;
forming an indented structure positioned at least about a portion of the side end surface, and a side of the side end surface proximal to the substrate is more indented inward compared to a side away from the substrate; and
forming a light emitting layer across the display area and the isolation region;
wherein the light emitting layer is provided with one or more breaks at one or more positions proximal the indented structure.

19. The method for manufacturing a display substrate according to claim 18, wherein the at least one structural layer comprises
a barrier layer of the base substrate, a buffer layer on the base substrate,
a first gate insulation layer on the buffer layer, a second gate insulation layer on the first gate insulation layer, an interlayer insulation layer on the second gate insulation layer.

20. The method for manufacturing a display substrate according to claim 19, further comprising forming a metal line between two layers of any two of a portion of the barrier layer, a portion of the buffer layer, a portion of the first gate insulation layer, a portion of the second gate insulation layer, and a portion the interlayer insulation layer, and wherein the method further comprises forming the indented structure at side end surface of the metal line.
